(19) United States
(12) Patent Application Publication
(10) Pub. No.: US 2007/0159187 A1
(43) Pub. Date: Jul. 12, 2007

(54) CORROSION DETECTION APPARATUS AND METHOD

(75) Inventors: Weiguo Chen, Shanghai (CN); Yu Zhang, Shanghai (CN); Gaorong He, Shanghai (CN); Peter Sam Allison, Conroe, TX (US); Yikang Gu, Shanghai (CN); Yao Chen, Shanghai (CN); Wei Cai, Shanghai (CN); Brian Walter Lasiuk, Waukesha, WI (US); Shengxian Wang, Shanghai (CN); Chang Wei, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/685,513

(22) Filed: Mar. 13, 2007

Related U.S. Application Data
(63) Continuation-in-part of application No. 11/290,671, filed on Nov. 30, 2005.

(51) Int. Cl. G01R 27/08

(52) U.S. Cl. 324/700

(57) ABSTRACT

A corrosion detection apparatus is provided. The corrosion detection apparatus is capable of detecting corrosion on a surface of a pipe or a vessel where the surface contacts a fluid that is corrosive to the surface. The corrosion detection apparatus includes a corrodible element having a contact surface; at least two electrodes that are in electrical communication with each other through a segment of the corrodible element; and a detector in communication with the at least two electrodes. The detector detects a characteristic impedance value from the at least two electrodes through the corrodible element segment.

### CROSS REFERENCE TO RELATED APPLICATIONS

This application is a continuation-in-part of U.S. patent application Ser. No. 11/290671, filed on Nov. 30, 2005.

### BACKGROUND

1. Technical Field

Embodiments of the invention may relate to a corrosion detector apparatus. Embodiments of the invention may relate to a method of detecting corrosion.

2. Discussion of Art

Some industrial processes may involve the use of a fluid corrosive that can degrade or corrode the equipment used in the processes. Such equipment may include piping, vessels, and heat exchangers. It may be desirable to monitor such degradation or corrosion for maintenance purposes.

General corrosion is widespread and occurs on a relatively large scale or relatively large area. General corrosion is relatively uniform on the surface of a pipe or vessels in the target system, or on a sensor. General corrosion damages and removes metal mass, which changes the geometry, i.e., thickness of the surface, and causes a degradation or depletion of original material. General corrosion compromises the structural rigidity and integrity of a pipe or vessel. Exemplary general corrosion can include, but is not limited to, large-scale surface oxidation, e.g., to form metal oxides. On the other hand, localized corrosion may be widespread or limited to only a few areas of the target system, but is relatively non-uniform and occurs on a relatively small scale. Exemplary localized corrosion can include, but is not limited to, pitting, environmental stress cracking (ESC), (hydrogen) embrittlement, and the like, as well as combinations thereof.

Degradation and corrosion may be estimated using a corrosion coupon. The coupon is exposed to a corrosive environment and periodically monitored. The corrosion rate can be calculated by measuring the weight loss of the coupon due to corrosion. The corroded coupons are examined to determine the type of corrosion.

Another monitoring technique measures the change in electrical resistance of a wire or sensor exposed to the corrosive environment over time. The changing electrical resistance of the wire or sensor indirectly correlates to the corrosion rate of the equipment. Rather than a wire, an electrodes changing polarization resistance is measured in linear polarization resistance (LPR). The changing polarization resistance of the electrode indirectly correlates to the corrosion rate of the equipment.

Another technique is electrochemical noise measurement, which is used in a fluid environment to measure localized corrosion. This technique senses changes in the locale using random bursts of current or potential that may occur during the corrosion process.

It may be desirable to have an apparatus for sensing corrosion that differs from those apparatus currently available. It may be desirable to have a method for sensing corrosion that differs from those methods currently available.

### BRIEF DESCRIPTION

In one embodiment, a corrosion detection apparatus is provided. The corrosion detection apparatus is capable of detecting corrosion on a surface of a pipe or a vessel where the surface contacts a fluid that is corrosive to the surface. The corrosion detection apparatus includes a corrodible element having a contact surface; at least two electrodes that are in electrical communication with each other through a segment of the corrodible element; and a detector in communication with the at least two electrodes. The detector detects a characteristic impedance value from the at least two electrodes through the corrodible element segment.

A method for detecting corrosion is provided in one embodiment. The method includes exposing a surface of a corrodible element segment to a fluid capable of corroding the corrodible element segment, and detecting a characteristic impedance value of the corrodible element segment.

### BRIEF DESCRIPTION OF DRAWINGS

With reference to the drawing figures, like numerals represent substantially the same parts from drawing to drawing.

FIG. 1 is a schematic illustration of impedance changes as a function of the surface of the sensor. FIG. 1A is a schematic illustration of an exemplary impedance circuit having a resistance, a capacitance and an inductance suitable for use with an embodiment of the invention.

FIG. 2 shows a simplified schematic of a linear resistive corrosion detection apparatus for detecting both general corrosion and localized corrosion constructed in accordance with an embodiment of the invention. FIG. 2A is an alternative arrangement of the sensor shown in FIG. 2. FIG. 2B is a two-dimensional alternative embodiment.

FIG. 3 shows a serpentine shaped corrosion detection apparatus for detecting both general corrosion and localized corrosion constructed in accordance with an embodiment of the invention.

FIG. 4 shows a swirl-shaped corrosion detection apparatus for detecting both general corrosion and localized corrosion constructed in accordance with an embodiment of the invention.

FIG. 5A shows an arrangement of the serpentine sensor of FIG. 3. FIG. 5B is a top view of a portion of the linear resistive corrosion detection apparatus isolated from FIG. 5A showing an idealized local corrosion. FIG. 5C is a side view of FIG. 5B. FIG. 5D is a schematic representation of the sensor in FIGS. 5B and 5C as an equivalent electrical circuit. FIG. 5E is an idealized graph of resistance and depth of local corrosion.

FIG. 6A shows a cross-sectional view of a total integrated corrosion detection apparatus on a chip, including the sensing element and electronics constructed in accordance with an embodiment of the invention. FIG. 6B shows a bottom view of FIG. 6A along with schematic circuit components.

FIG. 7 is a schematic view of the sensor shown in FIGS. 6A and 6B deployed in a pipe.

FIG. 8 is a schematic view of a central controller or CPU in field use with a plurality of the corrosion detection apparatus chips shown in FIGS. 6A and 6B.

FIG. 9A is a graph illustrating the aspect ratio of pit changes as a function of the base metal. FIG. 9B is a graph illustrating the sensitivity of a sensor of the invention and sample sensor after field deployment.

### DETAILED DESCRIPTION

Embodiments of the invention may relate to a corrosion detector. Embodiments of the invention may relate to a method of detecting corrosion.

As used herein, the term fluid includes liquids, gases and fluidized solids. Approximating language, as used herein throughout the specification and claims, may be applied to modify any quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value.

One aspect of the invention relates to a corrosion detection apparatus having the capability of detecting at least two different types of corrosion, when placed within, in contact with, or in proximity to a target system or apparatus for which corrosion detection and/or analysis is desired. The sensor is capable of detecting general corrosion as well as local or localized corrosion. While the target system can be made from any materials, a typical target system includes, but is not limited to metal pipes, vessels, containers, heat exchangers through which a corrosive fluid runs/circulates.

The fluid in the target system may cause damage to the system via chemical means (e.g., corrosion) or mechanical damage (e.g., erosion). In some embodiments, these conditions can include, but are not limited to, increased/decreased pressure, increased/decreased temperature, relatively high/relatively low flow rate, and the like, and combinations thereof. In one embodiment, the corrosive fluid is aqueous. In other embodiments, the corrosive fluid can include a heterogeneous component. Suitable heterogeneous component include solid particles, colloids, or the like. In one embodiment, the corrosive fluid can be a mixture of water, hydrocarbons, and organic solvents. Suitable aqueous fluids may include one or more of waste water, purified water, tap water, an aqueous salt solution such as saline or ocean water, or the like. Suitable hydrocarbons include mixtures or organic compounds. Examples of hydrocarbons include oil and petroleum reactants, and petrochemical intermediates and by-products.

Suitable industrial vessels and pipes are made from metals or metal alloys. Suitable metals include aluminum, copper, chromium, cobalt, iron, nickel, magnesium, tantalum, titanium, tungsten, zinc, and zirconium. Suitable metal alloys include aluminum alloys, copper alloys, iron alloys, nickel alloys, titanium alloys, magnesium alloys, chromium alloys, cobalt alloys, tantalum alloys, tungsten alloys, zinc alloys, and zirconium alloys. Suitable iron alloys may include steels. Tradename alloys suitable for use include HASTALLOY and INCONEL. The pipes and vessels in the target can alternately be made from non-metallic materials or combinations of metallic and non-metallic materials.

In one embodiment, a corrosion detection apparatus includes a sensing element. The sensing element has the same, or a similar, chemical composition to that of the fluid-contacting inner surface of the pipes in the target system to be monitored for corrosion. The sensing element can be made from any of the metals or alloys described above. In one embodiment, the sensing element has a similar surface finish as the fluid-contacting inner surface of the pipes of the target system. By having one or both of the same composition and surface finish, similar corrosive attacks should occur on both the target system and on the sensing element, and the corrosion rate should be about the same.

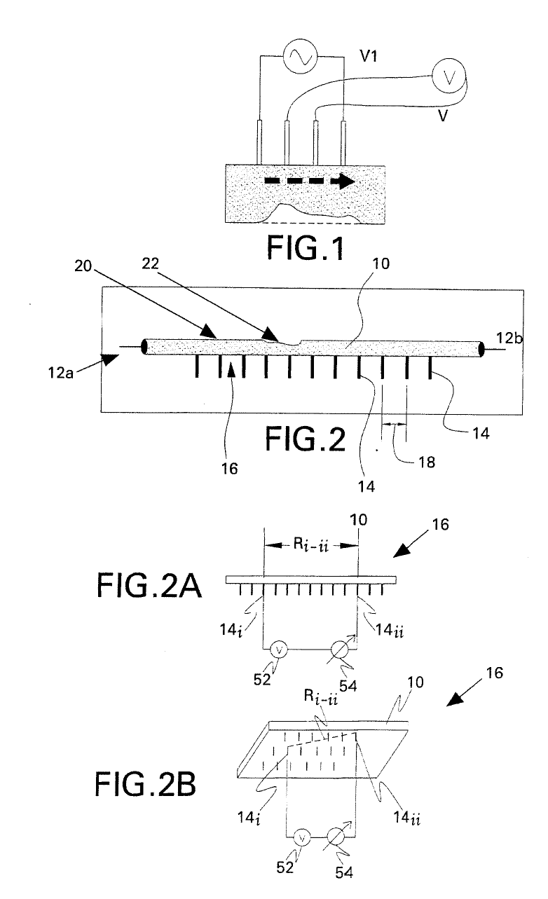

When a metallic surface of a pipe, a vessel or a sensor is corroded, its sheet resistance or impedance changes as a function of the geometry of the surface as illustrated in FIG. 1. The changes in resistance can be quantified in accordance to the following equation:

$${R}_{s} = \frac{π}{ln 2} \frac{{V}_{1} + {V}_{2}}{I} f ( \frac{{V}_{1}}{{V}_{2}} )$$

$$f ( {V}_{1} / {V}_{2} ) \begin{matrix}Van Der Pauw \\ correction factor\end{matrix}$$

This equation can be generalized to account for the more general circuit impedance via:

$${Z}_{s} = \frac{π ( {V}_{1} + {V}_{2} )}{ln 2 I} f ( \frac{{V}_{1}}{{V}_{2}} )$$

Where Rₛ is the resistance (and Zₛ is the impedance) across the pre-selected segment; V₁ and V₂ are the voltage across the same segment; and I is the current through same, as schematically depicted in FIG. 1. The voltage can be either direct current or alternating current. Experiments shoe that the changes in resistance are measurable in the milli-ohm range using standard measuring equipment. Embodiments of the invention are described with the change in the resistive properties of the circuit; however, the same principles apply to the reactive component of the sensing element impedance. The components of the impedance, resistive or reactive, are a function of the geometry of the electrodes, and alteration in the shape, spacing,

$$Z = {R}_{s} + j ( ω {L}_{s} - \frac{1}{ω {C}_{s}} )$$

or orientation of the electrodes will affect the impedance in a measurable amount. A generalized circuit is shown in FIG. 1A and governed by the following equation:

$$Z = {R}_{s} + j ( ω {L}_{s} - \frac{1}{ω {C}_{s}} )$$

where Z is the impedance, Rₛ is the circuit resistance, Lₛ is the circuit inductance, Cₛ is the circuit capacitance, and ω is the angular frequency.

Simultaneous measurement of general corrosion and localized corrosion on a single sensor can be accomplished with a linear resistive corrosion system, such as the one shown in FIG. 2. FIG. 2 shows a corrosion detection apparatus 1. The corrosion detection apparatus includes a linear resistive corrodible element 10, two sensor leads 12a, 12b, and measuring electrodes 14. The corrodible element can exhibit both general corrosion (indicated by reference number 20) and localized corrosion (indicated by reference number 22). The localized corrosion can include pitting. The sensor leads connect the corrodible element to an electrical power source (AC or DC) to supply electrical power to the corrosion detection apparatus. The electrodes are arranged in a linear array and are in electrical contact with the corrodible element and extend away from the corrodible element. Reference number 16 indicates segments of the corrodible element disposed between adjacent pairs of the electrodes. The electrodes include relatively thin electrically insulated wire conductors so that the amount of electrical power drawn away from the corrodible element is minimized. Reference number 18 indicates spacing or pitch between adjacent electrodes. The pitch along the corrodible element is selected to be about the same as the characteristic dimension of the expected localized corrosions for the particular metallurgy, process conditions, and fluid type. The differing aspect ratios of pitting in different metallurgies is shown in FIG. 9A.

When electricity is passed through the corrodible element via the sensor leads, one or more electrical properties can be measured between pairs of electrodes. In one embodiment, the electrical property that is measured is the resistance of each segment described by the above equation, collectively denoted by Rᵢ, where i is an integer in a range of from 1 to (n−1), where n is the number of electrodes arranged on the corrodible element. In other words, for n numbers of electrodes, there are n−1 numbers of the segments whose resistances are measurable.

The pairs of electrodes may be adjacent to one another, but non-adjacent electrodes may also be used to vary spacing or pitch. In other words, spacing or segment size can differ by selecting non-adjacent electrodes for measurements. Examples of such selection include adjacent electrodes, every other electrode, every third electrode, or random electrodes.

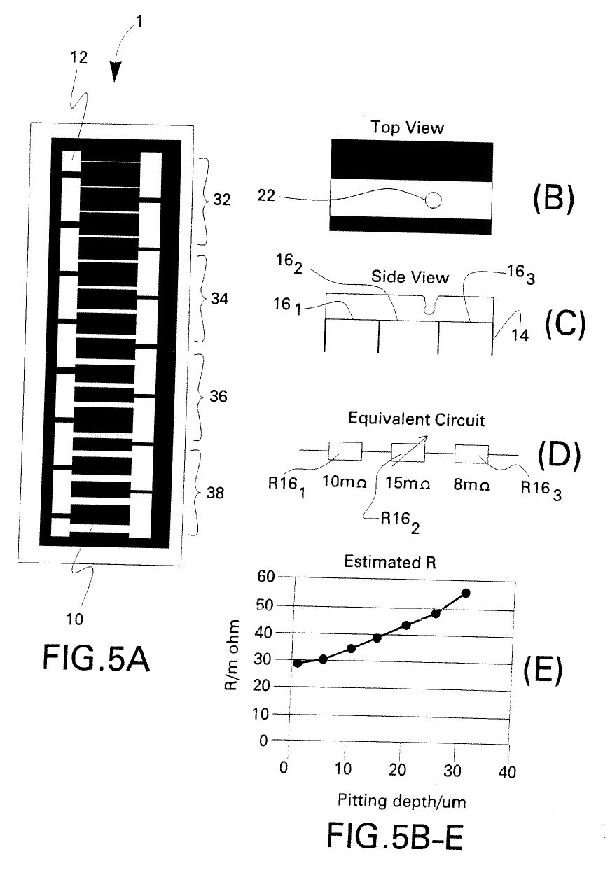

For example, the resistance of the corrodible element can be measured by applying a known DC or AC current through the sensor leads and by measuring the resulting voltage across pairs of electrodes. Alternatively, a known DC or AC voltage can be applied to the leads and the current through the segments the corrodible element can be measured. The impedance along the entire the corrodible element, or the sum of all the segments, can be ascertained. Before any corrosion occurs on the corrodible element, the initial resistance Rₒ should be substantially the same, for any segment on the corrodible element. At a given time t after the corrodible element is immersed in a corrosive fluid, any corrosion that occurs reduces the cross-sectional area of the corrodible element, and increases resistance in the electrode where the corrosion occurred, as discussed further below and shown in FIGS. 5B-5E.

The multiple impedance values of the segments between corresponding pairs of electrodes at any given time, individually denoted as Rᵢ(t), can be used for corrosion analysis or can be compared to the pre-corrosion Rₒ to get a differential value, ΔRᵢ(t), for corrosion analysis.

Alternately, a reference sensor 1_{ref} (not shown), containing a substantially similar conductive element 10_{ref} (not shown), can be embedded in an insulating substrate isolating the reference sensor from the corrosive environment but exposing it to similar environmental conditions, such as temperature and pressure, as the measuring detection apparatus. This reference sensor 1_{ref} can provide a non-corrosive Rₓ(t) value for comparison to Rᵢ(t). Rₓ(t) should is similar to the pre-corrosion Rₒ, when environmental conditions between the pre-corrosion environment, when Rₒ is measured and the corrosive environment, when Rₓ(t) is measured, are similar. Otherwise, the difference between Rₓ(t) and Rₒ can be indicative of such conditions, e.g., temperature drift. In this manner, temperature drifts can be corrected for more accurate readings. Alternatively, a thermocouple can be added to the sensor to directly measure the temperature of the sensor.

Either value, ΔRᵢ(t) or Rᵢ(t), for each segment can be plotted on the y-axis of a time-slice histogram or bar graph, for example, with the x-axis representing the position of the segments along the length of the corrodible element. If Rᵢ(t) is used, Rₒ or Rₓ(t) may also be plotted as a horizontal line on the histogram for comparison.

General corrosion can be ascertained by at least two methods. General corrosion can be indicated by relatively small differences between Rᵢ(t) and Rₒ or Rₓ(t), or by a uniform change between the electrode pairs.

Localized corrosion is indicated by relatively large differences between Rₓ(t) and Rₒ or Rₓ(t), or changes in only specific, discrete electrode pairs. Because resistance is a function of the cross-sectional area of segment 16ᵢ between the i^{th} and (i+1)^{th} the electrodes, the presence of localized corrosion between the (i+1)^{th} and the i^{th} electrodes means a smaller cross-sectional area in the particular segment therebetween and thus a higher measured resistance. In other words, localized corrosions can be detected by relatively higher resistance Rᵢ(t) at one or more segments when compared to other Rᵢ(t) values at other segments. On the other hand, general corrosion can be detected by more widespread increase of resistance along a higher number of segments.

Additionally, a single incidence of localized corrosion may significantly reduce the ability of electricity to flow through that localized corrosion, if that local corrosion substantially reduces or cuts through the thickness of the corrodible element. This produces a very strong signal that the corrosion has completely eroded the depth of the electrode.

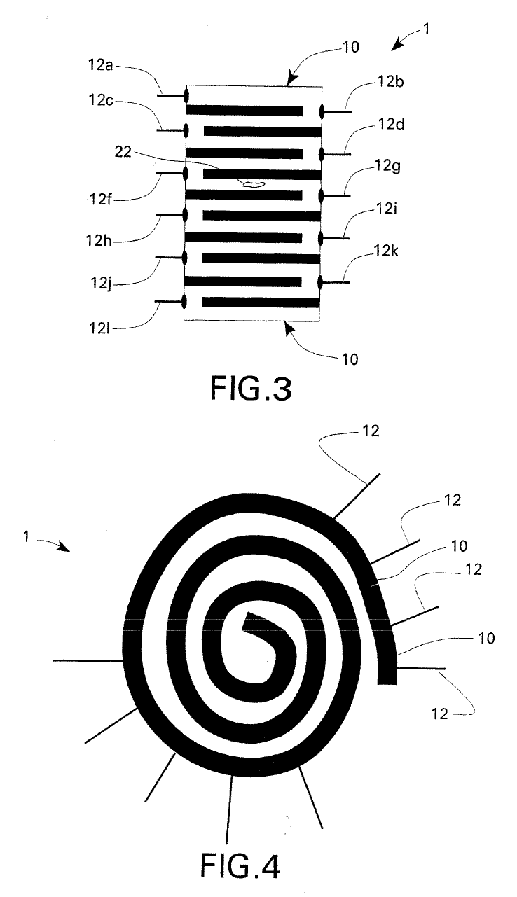

FIG. 3 shows a top view of a serpentine variation of the corrosion detection apparatus in FIG. 2. Here, the linear resistive the corrodible element is formed into a two-dimensional serpentine pattern on an electrically insulating substrate 30. The electrically insulating substrate extends into the spaces between the serpentine pattern of the corrodible element to ensure that electricity flows along the length of the corrodible element and that no electrical short occurs. In this embodiment, there is a plurality of sensor leads, 12a, 12b, 12c, . . . present to minimize the potential problem of localized corrosion isolating or cutting through the corrodible element. For example, if the corrodible element shown between the leads 12f and 12g is corroded through, the rest of the sensor can still be supplied with electricity through leads 12a-12f and 12g-12l. Not shown from the perspective in FIG. 3 is the plurality of electrodes oriented in the direction normal to the plane as shown. The serpentine pattern also minimizes the space required to contain a desired length of the corrodible element, and also provides a 2-D sensor while employing a linear element.

FIG. 4 shows a 2-D swirl-shaped variation of the corrosion detection apparatus in FIG. 2. Here, the corrodible element is formed into a two-dimensional spiral pattern on an insulating substrate (not shown). As in FIG. 3, electrodes (not shown) electrically connected to the corrodible element are oriented in the direction normal to the plane as shown. Sensor leads are also connected to the corrodible element to supply AC or DC electricity.

The dimensions of the corrodible element, such as cross-sectional area, are tailored to the characteristic dimensions of corrosion in the target system as well as the dynamic range of the sensor. An example of this is described above in the graph showing different aspect pitting ratios for different materials. The dimensions may depend upon the specific materials in the target system, the corrosive fluid present during the duration of the corrosion detection/analysis and the type of flow, e.g., laminar or turbulent, in the target system, and the amount of corrosion that is expected. By varying the cross-sectional area of multiple corrodible elements, as in the sensor of FIG. 5A, the characteristic dimensions of localized corrosion can be determined. This determination can be accomplished by several methods. One method estimates the size of localized corrosion events in the long term by accelerating the corrosion rate of the system, e.g., by increasing temperature and/or by increasing the concentration of a particularly corrosive component of the fluid. This uses a side-stream sampling device. Another involves extrapolating the long-term size of localized corrosion events from abbreviated measurements of real-time corrosion by the corrosive fluid under operating conditions. The expected dimensions of localized corrosion events in the long-term are related to the size of the corrodible element.

In one embodiment, the segment spacing between the electrodes, and the size and shape of the electrodes are on the order of the dimensions of localized corrosion effect (e.g., the pit diameter), and the dynamic range required or the measurement. The corrosion rates for some industrial systems are shown in FIG. 9B, overlaid with sensitivity bands of different electrode geometries. FIG. 9B shows real sensor data from field deployments. The sensitivity of the sensor can be selected by choosing the appropriate electrode geometry.

The total number of electrodes electrically connected to the corrodible element can be based on the spacing and on the length L of the corrodible element, or on the absolute size of the corrosion detection apparatus. In general, there is no limit to the number of electrodes that can be deposited on a smart coupon. However, for use in a nominal 1-2″ diameter pipe, using moderate power consumption, and a good statistical sampling of many electrodes to disentangle local and general corrosion, about 16 electrodes should suffice. In other embodiments, the corrosion detection apparatus includes from about 3 to about 20 electrodes, from about 20 to about 50 electrodes, from about 50 to about 100 electrodes, from about 100 to about 200 electrodes, or more than about 200 electrodes.

Referring again to FIG. 5A, the corrosion detection apparatus includes a plurality of corrodible elements having varying cross-sectional areas, and each is disposed between pairs of electrodes as shown. In this example, the corrodible elements have progressively increasing cross-sectional areas 32, 34, 36, 38 with cross-section 32 being the smallest and cross-section 38 being the largest. In the embodiment illustrated by FIG. 5A, the sensor leads supply the electrical power, as well as measuring the resistance Rₛ in each corrodible element. As corrosion attacks the corrodible element, the ones with the smallest cross-sectional areas would be the first to no longer conduct electricity or the resistance would be too large to measure. As the corrosion continues, the corrodible element should progressively stop conducting electricity in direct relation to the size of their cross-section area. Hence, when the corrodible element with the smaller cross-sectional area stops conducting electricity, then the size of the corrosion is substantially the same as the smaller cross-sectional area. When the corrodible element with next smaller cross-sectional area stops conducting electricity then the corrosion is substantially that size, and so on. In this example of the sensor in FIG. 5A, the electrodes are optional because the sensor leads can be used both to provide electrical power and to measure current and voltage. The cross-sectional area of the corrodible element also affects the resistance of the corrodible elements, i.e., smaller cross-sectional area, would yield higher measured resistance.

In another embodiment also illustrated by FIG. 5A, the corrodible elements are used with electrodes (not shown) similar to that in FIG. 2. A portion of the corrodible element with local corrosion is enlarged and shown in FIGS. 5B and 5C. As the local corrosion occurs, the cross-sectional area of the corrodible element is reduced. One way of ascertaining the size and/or location of corrosion is illustrated in FIGS. 5C and 5D. This portion of the corrodible element is divided, for example, into 3 segments indicated by reference numbers 16₁, 16₂ and 16₃ between the electrodes. The local corrosion is located in the segment designated 16₂. The resistance of each segment is represented schematically in FIG. 5D by an equivalent electrical circuit. The resistance of segments 16₁ and 16₃, i.e., R-16₁ and R-16₃, are constant or relatively constant with no local corrosion occurring thereon. The resistance of segment 16₂, i.e., R-16₂, varies because the size of the corrosion increases with time. Also, R-16₂ is higher than R-16₁ and R-16₃ due to the reduced cross-section caused by corrosion. The graph shown in FIG. 5E schematically represents the increase in resistance as the depth of the corrosion increases.

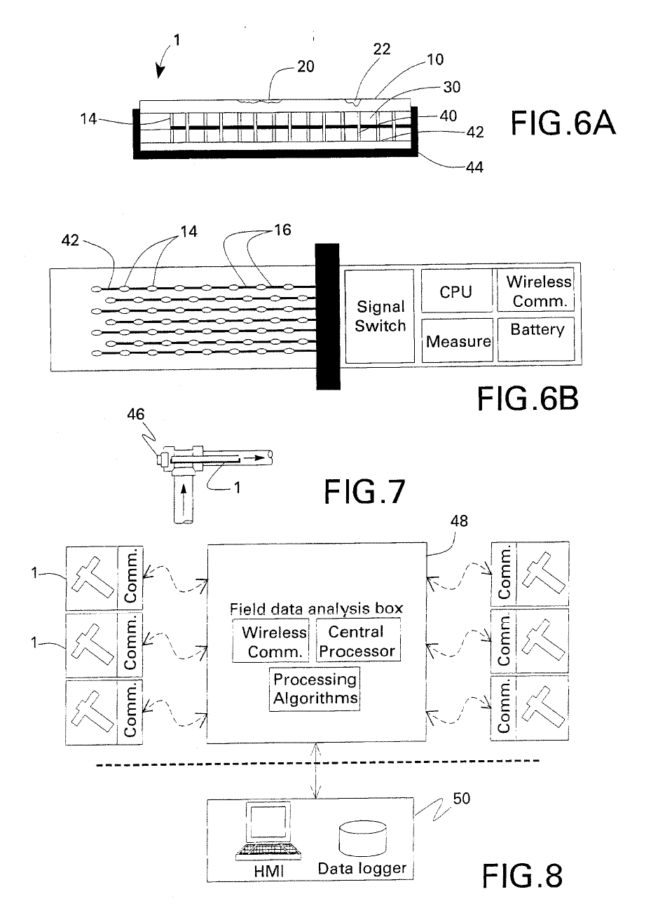

FIGS. 6A and 6B illustrate another embodiment where the corrodible element communicates with a controller system (not shown). In particular, the corrodible element is integrated with the acquisition, processing, and communications electronics on a chip in a micro-electro-mechanical (MEMs) system. As shown, the corrosion detection apparatus comprises the corrodible element disposed on top showing both general and local corrosion. A plurality of electrodes connects the corrodible element to a central processing unit (CPU)and other circuitries via top electrical connecting layer 40 and bottom electrical connecting layer 42, as known in the art. As shown in FIG. 6B, the processing and communicating modules include a central processing unit, a measuring module (including voltmeter, ohmmeter and/or amp meter), a signal switch to select a particular corrodible element to measure, a battery and a wireless communication module. Suitable wireless communication module employ radio frequency signals, e.g., RFID technology. The sensor leads can be designed such that each lead is an active element in a resonant circuit, each responds to a specific frequency. The specific resonant frequency or its amplitude changes when corrosion occurs at the surface of the senor leads, and a receiver detects this change. The receiver may be mounted distantly outside the pipe. The receiver can be a radio wave generator so that the sensor leads do not need power. A series sensor leads can also be designed to respond to a series of resonant frequency, therefore the corrosion profile can be obtained by correlating the extent of corrosion to the resonant frequencies. An anti-corrosion coating 44 is applied to protect the electrodes and circuitry from corrosion. In an alternative embodiment, a housing protects the circuitry.

Small MEMs sensing elements may be of similar construction to those previously describes or the electrodes may be deployed on a sheet of material. As such the electrodes measure and map the changes in the sheet current, rather than the current flowing in discrete electrodes. This sensor is also known as “RCM on a chip”.

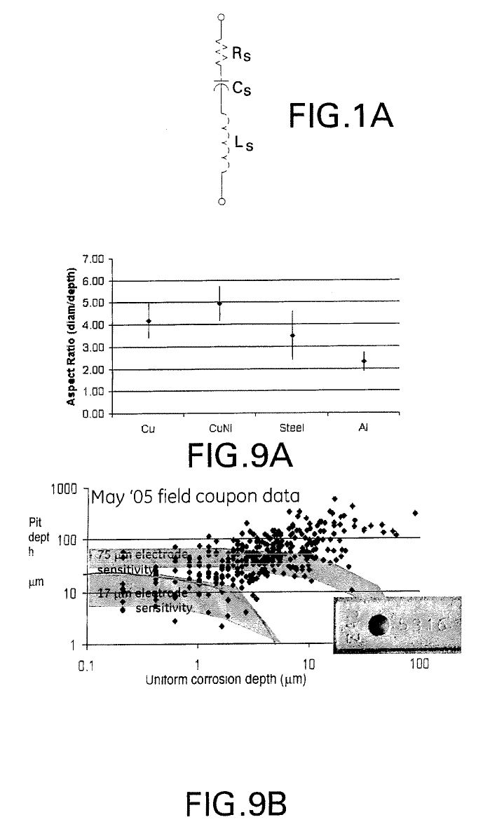

An exemplary deployment of chip as a corrosion detection apparatus is shown in FIG. 7. An exemplary location includes corners or bends, where the flow can be turbulent, but there is no barrier to deploying the sensor in any location that is commensurate with accommodating its physical envelope. The corrosion detection apparatus is attached to a pipe plug 46 such that corrosion detection apparatus is in the flow stream. The processing and communicating modules can be reused and are embedded in the plug. Due to the wireless communication capability, a plurality of corrosion detection apparatuss can be deployed wirelessly. Each sensor/chip can communicate with a data analysis module 48 as shown in FIG. 8. In addition to the ability to communicate wirelessly, the field module may have a CPU and data processing modules, as shown. The field module connects to a remote module 50. The remote module may include computers and data logger or data storage, via the Ethernet or LAN connections.

The surface finish of the sensing element should be similar to that of the metallurgy of the target system. Sensors may be deployed in pairs. A suitably polished sensor similar to that of the target system may be used with another sensor that has the active element that has been slightly abraded. Such a marred or imperfect coupon would tend to corrode or be subject to a corrosive attack on shorter time scales than a nominal coupon, because localized corrosive attacks commence when the protective surface oxide layer(s) is broken and a direct attack on the base metal can be initiated. As such, a nominal sensor, much like a pipe or vessel wall have to have the protective surface layers degraded before a corrosive attack on the base metal can commence. This would under estimate the corrosion rate should there be physical defects in the pipe or vessel due to mechanical such as scratching, marring, or any physical damage during fabrication, transportation, installation, etc. of the vessel or piping. By deploying a marred or imperfect coupon that already has some surface damage where the protective oxide coating is compromised, a more rapid attack can be measured. Therefore, the measurements of this pair of coupons would provide a range of corrosion attacks that may be occurring in the system, including a worst case (i.e. protective oxide films compromised) and a best case (i.e. protective oxide film is not compromised). A reference sensor, described above, can also be deployed with such pair.

Because both the sensor and associated processing electronics are small, the sensor can be embedded into the infrastructure itself. That is, it can be placed into the substrate or wall of the pipe or vessel, and become part of the infrastructure. The sensor can be embedded into a pipe or vessel material without requiring additional machinery to fix it within the pipe or vessel. Replacement pipe sections may be supplied with built-in sensor arrays.

Depending upon the desired electrical properties to be measured and/or analyzed and upon the power supply available, direct current and/or alternating current may be supplied through the sensor leads. Whatever power is supplied through the sensor leads, it may include a (DC) component and/or a variable or periodic (AC) component. Examples of possible power supplied may include, but is not limited to, a sinusoidal voltage/current having a relatively constant maximum amplitude and frequency, a square or ramping wave of voltage/current having a relatively constant maximum amplitude and frequency, a sinusoidal voltage/current having changing frequency/periodicity, a square or ramping wave of voltage/current having changing frequency/periodicity, a sinusoidal voltage/current having changing amplitude, a square or ramping wave of voltage/current having changing amplitude. An electrical source, such as industrial electric power or battery, is used to supply power to sensor leads. The sensor leads may be electrodes or hard wires connected to sensor elements. Other power sources, such as induction coils for creating/focusing magnetic fields and circuits for converting radio frequencies into electric current/voltage, are contemplated for supplying power to sensor leads.

Suitable electrically insulating substrates may include dielectric materials. Suitable dielectric materials may include metal oxides, metal nitrides, metal oxynitrides, or SiLK. Other suitable dielectric materials may include non-electrically-conductive polymer resins. Suitable non-electrically-conductive polymer resins may include epoxy resins, phenolic resins, polyolefins, polysulfones, polyetherimides, polyimides, melamine resins, alkyd thermoset resins. Suitable polyolefins may have a high crystallinity. Suitable high crystallinity polyolefins may include HDPE, i-PP, and the like. Other suitable polyolefins may include partially or completely halogenated poly(alpha-olefin)s. Suitable halogenated poly(alpha-olefin)s may include PVC, PVDC, PVDF, PTFE, FEP, and poly(perfluoroacrylate)s. Thermoplastic materials may be used, too, such as polycarbonates. The electrically insulating polymers may include one or more reinforcing agents. The reinforcing agents may include non-conductive or semi-conducting fibers, permeation/diffusion modifiers, and intercalated clays.

In an alternative embodiment shown in FIG. 2B, each of the plurality of electrodes functions as a sensor lead. Any two electrodes 14ᵢ and 14ᵢᵢ can be selectively connected to a power source 52. A measuring device 54 can be included in the circuit to measure the current or voltage or both. A resistive value Rᵢ-ᵢᵢ between electrodes 14ᵢ and 14ᵢᵢ can be ascertained. In another embodiment shown in FIG. 2B, the sensor apparatus includes a two-dimensional rectangular corrosive element having a plurality of electrodes dependent therefrom as shown in FIG. 10. In this case, all electrodes are electrically connected to each other at or by the corrodible element. Any two electrodes 14ᵢ and 14ᵢᵢ, including adjacent electrodes can be selectively connected to the power source and the meter. In the embodiments shown in FIGS. 2A and 2B, if all adjacent pairs of electrodes are measured, and general and local corrosions can be ascertained as described above. Any random pairs of electrodes can be interrogated to yield information about any region of interest.

Another aspect of the invention relates to a method for real-time detection of at least two different types of corrosion (e.g., general corrosion such as surface metal oxidization and localized corrosion such as pitting) using at least one corrosion detection apparatus.

In one embodiment, the inventive method includes the steps of: providing at least one corrosion detection apparatus, which contains one or more corrodible elements, sensor leads, electrodes disposed on the corrodible elements, and an insulating substrate; providing at least one power source for providing power to the sensor; electrically dividing the corrodible elements into segments between pairs of electrodes; and collecting, manipulating, interpreting, monitoring, transmitting, and/or storing data regarding the resistance of the segments to ascertain information relating to the general and local corrosions. This method can provide a real-time corrosion profile.

In addition, capturing/sampling (collection) of various corrosion data either constantly or at repeated/regularly-spaced times/time intervals can yield increased corrosion information about the target system and corrosive fluid environment. Such a corrosion detection system is an improvement compared to having a field engineer manually inspect corrosion coupons and determine weight loss, not more often than once per month.

The embodiments may aid in the collection, monitoring, and/or storage of corrosion data for transmission, manipulation, and/or interpretation remotely from the target system site allows for a determination of corrosion mode without visual inspection; data sampling at arbitrary times, or data sampling at repeated/regularly-spaced times/time intervals offers real-time corrosion information and history, which allows direct correlation of corrosion events with critical target system events (independent or integrated monitoring); and increased capability for measurement accuracy/precision, as what is being measured is the change in one or more electrochemical properties of the conductive sensor element(s) on the substrate, allowing a direct correlation with corrosion behavior; in some cases in the prior art, only the properties of corrosive fluid environment, such as with electrochemical noise (ECN) techniques, only allowing indirect correlation with corrosion behavior.

The foregoing examples are illustrative of some features of the invention. The appended claims are intended to claim the invention as broadly as has been conceived and the examples herein presented are illustrative of selected embodiments from a manifold of all possible embodiments. Accordingly, it is Applicants' intention that the appended claims not limit to the illustrated features of the invention by the choice of examples utilized. As used in the claims, the word “comprises” and its grammatical variants logically also subtend and include phrases of varying and differing extent such as for example, but not limited thereto, “consisting essentially of” and “consisting of.” Where necessary, ranges have been supplied, and those ranges are inclusive of all sub-ranges there between. It is to be expected that variations in these ranges will suggest themselves to a practitioner having ordinary skill in the art and, where not already dedicated to the public, the appended claims should cover those variations. Advances in science and technology may make equivalents and substitutions possible that are not now contemplated by reason of the imprecision of language; these variations should be covered by the appended claims.

We claim:

1. A corrosion detection apparatus capable of detecting corrosion on a surface of a pipe or a vessel where the surface contacts a fluid that is corrosive to the surface, the apparatus comprising:
a corrodible element having a contact surface;
at least two electrodes that are in electrical communication with each other through a segment of the corrodible element; and
a detector in communication with the at least two electrodes, wherein the detector is capable of detecting a characteristic impedance value from the at least two electrodes through the corrodible element segment.

2. The corrosion detection apparatus as defined in claim 1, wherein the corrodible element segment comprises the same material as a material from which the pipe or the vessel is formed.

3. The corrosion detection apparatus as defined in claim 1, wherein the corrodible element defines a serpentine or spiral pattern.

4. The corrosion detection apparatus as defined in claim 1, wherein the corrodible element segment is linear.

5. The corrosion detection apparatus as defined in claim 1, wherein the at least two electrodes are part of a plurality of electrode pairs, each pair of which defines a corresponding corrodible element segment.

6. The corrosion detection apparatus as defined in claim 5, wherein each corresponding corrodible element segment has the same dimensions as each other corresponding corrodible element segment.

7. The corrosion detection apparatus as defined in claim 5, wherein each corresponding corrodible element segment is formed from a different material, or each corresponding corrodible element segment has a different surface treatment.

8. The corrosion detection apparatus as defined in claim 5, wherein at least one pair of the plurality of electrode pairs is configured to not contact the fluid during use of the corrosion detection apparatus, and is configured to provide a reference point for at least one environmental variable that affects plurality of electrode pairs selected from the list consisting of temperature, pressure, humidity, and vibration.

9. The corrosion detection apparatus as defined in claim 1, wherein the contact surface has the same finish as the surface of the pipe or the vessel.

10. The corrosion detection apparatus as defined in claim 1, further comprising a protective coating secured to the contact surface and to the surface of the pipe or the vessel.

11. The corrosion detection apparatus as defined in claim 10, wherein the protective coating that is secured to the contact surface has a mar, defect or scratch.

12. The corrosion detection apparatus as defined in claim 1, wherein the detector is an electronic chip package mounted on the corrodible element.

13. The corrosion detection apparatus as defined in claim 12, wherein the chip communicates with a field analysis module.

14. The corrosion detection apparatus as defined in claim 1, wherein the corrodible element segment has at least one dimension commensurate with a pitting dimension characteristic based on the metallurgy of the corrodible element.

15. The corrosion detection apparatus as defined in claim 1, wherein the characteristic impedance comprises electrical resistance or reactive impedance.

16. The corrosion detection apparatus as defined in claim 1, wherein the characteristic impedance changes in response to a change in the contact surface.

17. The corrosion detection apparatus as defined in claim 16, wherein the change is caused by at least one of local corrosion, general corrosion, or erosion.

18. The corrosion detection apparatus as defined in claim 1, wherein the corrodible element is embedded in an electrically insulated material, so that the electrically resistive corrodible element does not contact itself electrically.

19. A method, comprising:
exposing a surface of a corrodible element segment to a fluid capable of corroding the corrodible element segment; and
detecting a characteristic impedance value of the corrodible element segment.

20. The method as defined in claim 19, further comprising comparing the detected characteristic impedance value to a baseline value to determine if corrosion exists on the corrodible element segment surface.

21. The method as defined in claim 19, further comprising:
exposing a surface of another corrodible element segment to the fluid;
detecting another characteristic impedance value of the another corrodible element segment; and
comparing the characteristic impedance values of the corrodible element segment to the another corrodible element segment to determine if corrosion exists and whether the corrosion is general corrosion or local corrosion.

22. The method as defined in claim 19, further comprising securing a corrodible element comprising the corrodible element segment to a pipe or to a vessel so that the fluid capable of corroding the corrodible element segment also contacts a surface of the pipe or of the vessel during the exposing of the corrodible element segment to the fluid.

23. The method as defined in claim 22, further comprising matching at least one of material or surface finish of the corrodible element segment to a corresponding material or surface of the pipe or the vessel.

24. The method as defined in claim 19, further comprising determining one or both of a corrosion type or a corrosion amount of a pipe or a vessel based on the detected electrical impedance value.

25. A system, comprising:
a corrodible element having a surface segment configured for exposure to a fluid capable of corroding the corrodible element segment; and
means for detecting a characteristic impedance value of the corrodible element segment.

26. The system as defined in claim 25, further comprising means for determining corrosion in a pipe or a vessel in fluid contact with the corrodible element.
